(19) United States
(12) Patent Application Publication
(10) Pub. No.: US 2026/0030412 A1
(43) Pub. Date: Jan. 29, 2026

(54) FEEDFORWARD CONTROL USING GAUSSIAN PROCESS

(71) Applicant: UVic Industry Partnerships Inc., Victoria (CA)

(72) Inventors: Keivan Ahmadi, Victoria (CA); Mohammadmahdi Mehrabi, Victoria (CA)

(73) Assignee: UVic Industry Partnerships Inc., Victoria (CA)

(21) Appl. No.: 18/785,446

(22) Filed: Jul. 26, 2024

(51) Int. Cl. G06F 30/27; G05B 19/418

(52) U.S. Cl. CPC G06F 30/27; G05B 19/4183

(57) ABSTRACT

Feedforward control uses a Gaussian process representation of system input to derive an optimum input for a desired output trajectory over discrete sample times. A model provides a forward transfer function. A kernel function, having selectable parameters, provides a prior covariance matrix of the Gaussian process. A posterior mean of the system input can be derived by Bayes' theorem, based on the model, the kernel function, and the desired output trajectory. The posterior mean predicts system output and, thereby, tracking error. The kernel function parameters are selected to optimize the tracking error. The corresponding posterior mean provides optimized system input for the desired output trajectory. Disclosed techniques are applicable even when model inversion is unstable. Disclosed techniques can be applied in segments, saving computation resources and also suitable for adaptive control.

### BACKGROUND

Feedforward is widely used in control systems instead of, or in addition to, feedback. Feedforward control can utilize knowledge of a system's transfer function to precompute and apply an input designed to achieve a desired response. Because feedforward techniques attempt to compensate for prospective errors before they occur, feedforward control can sometimes provide lower average (e.g. root-mean-square (“RMS”)) tracking error than a comparable feedback system which can only compensate for errors that have already occurred. However, the dynamical characteristics of systems can often be susceptible to instabilities. Using a z-plane description, a forward transfer function G(z) can model the system operation as input→G(z)→output. In principle, an input for a desired output can be obtained using the inverse transfer function: output→G(z)⁻¹→input. A zero z0 of the forward transfer function, e.g. G(z0)=0, can correspond to a pole at z=z0 in the inverse transfer function G(z)⁻¹. If z0 is outside the unit circle, input estimation for feedforward control can be unstable. Such systems are called non-minimum phase (NMP) systems. A variety of techniques have been applied to derive well-behaved inputs for such systems. Some simply ignore the unstable pole and can be prone to fundamental inaccuracy, e.g. tracking error, particularly if the ignored pole is close to the unit circle. Other techniques can rely on a specialized set of basis functions, and have limited applicability. Accordingly, there remains a need for improved technologies to utilize feedforward control in NMP system.

### SUMMARY

In brief, examples of the disclosed technologies use a Gaussian process representation of a system input to derive an optimum input for a desired output trajectory. A model of the system is obtained. The model maps system input to system output. A Gaussian process representation of the system input has a mean and a covariance matrix. A kernel function having one or more selectable parameters imposes a prior probability distribution on the covariance matrix. A desired output trajectory is obtained. A posterior mean of the system input, which is predicted to lead to the desired trajectory, is dependent on the kernel function, the model, and the desired trajectory of the system output. Bayes' theorem can be applied to determine the posterior mean. In turn, the posterior mean predicts a system output. A tracking error quantifies deviations of the predicted system output from the desired trajectory. Respective values of the selectable parameter(s) of the kernel function are determined so as to optimize a predetermined metric which incorporates the tracking error. The posterior mean of the Gaussian process corresponding to these parameter values is determined, and a description of optimized system input (for the desired trajectory) is outputted based on this posterior mean.

In further examples, the overall time duration (or another independent variable) is divided into segments, and the Bayes' theorem can be applied to successive segments, constrained by previously determined system inputs for earlier sample times. Segments can overlap. The system input can be optimized over the entire trajectory by varying selectable parameter(s) of the kernel function.

The foregoing and other objects, features, and advantages of the invention will become more apparent from the following detailed description, which proceeds with reference to the accompanying figures.

### BRIEF DESCRIPTION OF THE DRAWINGS

FIG. 1 is a diagram of example operations on a dynamical system according to the disclosed technologies.

FIG. 2 is a flowchart of a first example method according to the disclosed technologies.

FIG. 3 is a chart illustrating comparative advantage of an example of the disclosed technologies.

FIG. 4 is a flowchart of a second example method according to the disclosed technologies.

FIG. 5 is a diagram illustrating recursive application of disclosed technologies for some examples of the second method.

FIG. 6 is a diagram of an example machine tool environment in which disclosed technologies can be employed.

FIG. 7 is a diagram of an example 3-D printer environment in which disclosed technologies can be employed.

FIG. 8 is a diagram of an example vehicle environment in which disclosed technologies can be employed.

FIG. 9 is a set of images illustrating example behavior of disclosed technologies in the face of vibration.

FIG. 10A-10C are charts illustrating an example of model extraction which can be used with the disclosed technologies.

FIG. 10D shows a representation of the model determined in FIG. 10B.

FIGS. 11A-11I are a set of diagrams and tables providing working details of a third example of the disclosed technologies.

FIG. 12 is a diagram schematically depicting a computing environment suitable for implementation of disclosed technologies.

FIG. 13 is a diagram schematically depicting computing devices operating in conjunction with a computing cloud for implementation of disclosed technologies.

### DETAILED DESCRIPTION

### Introduction and Overview

Feedforward is often desirable in control systems, instead of or in addition to feedback. Whereas feedback control can compensate for errors that have already occurred, feedforward control can utilize a model of the system's transfer function to precompute drive input to the system to avoid or minimize prospective errors. Accordingly, deviations from a desired trajectory can be avoided or minimized, and smoother system operation can be achieved with lower operating power compared to a system relying only on feedback control.

The system transfer function derives output from input. Feedforward control attempts to derive input from desired output, which is the inverse operation. However, in many systems of interest, a stable transfer function can have an unstable inverse, which can lead to oscillatory or divergent behavior with feedforward control.

A variety of approaches have been used to circumvent this problem. In some approaches, the unstable pole in the inverse of the transfer function is simply ignored. Such approaches are prone to fundamental inaccuracy, e.g. tracking error, particularly if the ignored pole is close to the unit circle.

Another approach relies on basis functions, in particular spline functions. That is, the input is decomposed into a linear combination of basis functions, the weights of which are determined to minimize the output tracking error. This approach can be applied over an entire trajectory or in segments, however the segmented implementation is limited to a particular set of basis function, namely spline functions, and may fail to produce a stable input solution when the system transfer function has a zero close to the unit circle in the z-plane. That is, the basis function approach is often unsuitable for adaptive systems where a later portion of a desired trajectory may not be known at the time an earlier part is being executed.

The disclosed technologies take a different approach to feedforward control. Rather than connecting a sequence of precisely specified sample points by a function, each sample point is treated as a random variable with an associated probability distribution. The collection of input sample points can form a Gaussian process. Connection between the sample points occurs through a covariance matrix rather than by a function. Each element of the covariance matrix provides the covariance (e.g. correlation) between a respective pair of the sample points. The covariance matrix can be specified by a kernel function, many of which are available to select from. As an illustration, a kernel function such as H0·exp(−|i−j|/H1) can be used to specify the covariance between sample points i, j. That is, nearby sample points can have high correlation while farther sample points can have low correlation. H0 and H1 are selectable parameters, collectively {H}, which can be used to tune the posterior input and reduce tracking error.

The probabilistic description of sample points lends itself to model inversion e.g. using Bayes' theorem. That is, the likelihood of some output Y contingent on a given input U, p(Y|U) can be expressed in terms of a model of the system transfer function. As described further herein, Bayes' theorem can be applied to determine the inverse conditional probability p(U|Y′), namely the posterior probability of input U for a desired output trajectory Y′. The means of p(U|Y′) can represent an optimum input sequence for achieving Y′, while the variances of p(U|Y′) can provide information as to the robustness of this input sequence. Notably, some sample points can have low variance, indicating that the values of these input samples may be critical, while other sample points may have high variance indicating that the precise values of these input samples have a large tolerance range.

The disclosed Gaussian process techniques offer numerous advantages over conventional techniques. First, the disclosed technologies can be applied to successive segments of a desired trajectory, saving on computation and allowing feedforward control to be applied adaptively in scenarios where the desired trajectory evolves after the system is in flight. Additionally, the Gaussian process approach is not limited to any specific kernel function. Thus, if one kernel function does not perform well for an application, another kernel function can be used. This is in marked contrast to the basis function approach, segmented application of which can be limited to a particular set of spline functions. The Gaussian process approach can be efficiently applied to a very wide range of systems. Furthermore, the Gaussian process approach can provide good tracking solutions even when the inverse transfer function is unstable, where basis function and other approaches fail. Segmented optimization can also provide significant computation savings. Still further, the variance of the posterior probabilities provide information as to robustness of the optimum input, such information not being available through other techniques. The probabilistic description is also suitable for dynamical systems whose model may not be accurately known.

These and other advantages of the disclosed technologies are further brought out below.

### Application of Bayes' Theorem

Given a model G specifying a forward transfer function of a system, examples of the disclosed technologies apply Bayes' theorem to a Gaussian process representation of the system input U, in order to invert the model G and obtain a feedforward control input U′ for a desired output Y′. In such an approach, p(U) can represent the prior probability distribution of input U, having no knowledge of the desired output. Without loss of generality, p(U) can be taken to have zero mean. As a Gaussian process, p(U) can have a Gaussian distribution, with covariances defined by a kernel function as described herein. p(Y) can have means defined by desired output Y′. For a Gaussian process U and a linear model G, output Y can also be a Gaussian process, and the shape of p(Y) can also be Gaussian. In some examples, the amplitude or width (which can be inversely related to each other) can be determined based on allowed tolerances for Y′. In other examples, the amplitude or width of p(Y) can be left unspecified initially, for subsequent resolution by normalization. Then, the likelihood p(Y|U) can be obtained by application of the model G. Finally, Bayes' Theorem can be applied to obtain the posterior probability p(U|Y), which is the probability distribution of input U, conditioned on desired output Y. Following Bayes' Theorem, p(U|Y)=p(Y|U) p(U)/p(Y). The mean of p(U|Y) can provide the desired control input U′ for the desired output Y′.

### Terminology

A “coordinate” is a number, optionally with a unit, that indicates a position or orientation of a point or object in space. Common coordinates can be linear or angular.

A “criterion” is a specified condition on the basis of which a decision can be made.

A “dynamical system” is a system that can evolve over time responsive to inputs and, in some cases, an initial state. The evolving system can be described by its state, which can be an output of the system. The relationship between inputs (and optionally initial state) and system evolution (e.g. output) is termed the “dynamics” of the system, and can be defined or approximated by a model. Examples of dynamical systems to which disclosed technologies can be applied include machine tools or vehicles: inputs can include drive signals to motors or other actuators, and outputs can include spatial coordinates (position and/or orientation) of driven components such as tool heads, workpiece stages, or a vehicle itself. System inputs are denoted as symbols beginning with U and outputs are denoted as symbols beginning with Y. U can refer to generic or prior system input variables, U1 refers to posterior system inputs which may not be optimized, U2 refers to optimized system inputs, and U′ refers to optimized system input over an entire time span of interest T. In some examples U′ and U2 can be the same while, in other examples, U′ can be formed from aggregating U2 (or portions thereof) over multiple segments.

Given a characteristic dependent on one or more independent variables, a “Gaussian process” is a description of the characteristic as a collection of random variables at respective values of the independent variable(s). To illustrate, the characteristic can be a driving input to a machine tool or vehicle at a succession of sampled times. Distinct random variables can represent the driving input at respective sample times. The Gaussian process can be described by a mean and a covariance matrix. To illustrate, the mean can be a collection of the expectation values of the characteristic over respective sampled times. The covariance matrix can represent correlation between the characteristic at any two sampled times. Often, covariance values can be higher for nearby sample times than distant sample times, but this is not a requirement. To illustrate, a periodic characteristic can have high values of covariance between sample times which are separated by an integer number of time periods. Diagonal elements of the covariance matrix can indicate the variability the characteristic at a respective sample time: a high value diagonal element indicating low variability, and a low value diagonal element indicating high variability.

The term “description” is used to distinguish a representation of a physical quantity from the physical quantity itself. In examples, the physical quantity can be an electrical drive signal input to a system, or a trajectory resulting therefrom. That is, systems discussed herein can be tangible, such as machine tools or vehicles, but can be described in mathematical form for the purposes of feedforward control according to the disclosed technologies. Accordingly this disclosure sometimes distinguishes a physical input (e.g. an electrical signal applied to a motor) from a description of the input which can be determined using the disclosed technologies or which can be determined as a Gaussian process. Similarly, a physical output (e.g. a trajectory or position of a vehicle) is sometimes distinguished from a description or prediction of that output.

The term “iteration” refers to each of multiple times a given operation or sequence of operations is performed. A sequence of iterations is dubbed a “loop”. A loop capable of iterating multiple times can sometimes execute just one iteration. An iteration of a loop need not execute all operations in the loop, but can terminate or exit early if a termination condition is met.

A “kernel function” is a function defining covariance between samples of a Gaussian process input.

A “machine tool” is an apparatus for cutting or otherwise changing the shape of an object (dubbed a “workpiece”). A machine tool can operate by a subtractive process, such as milling or etching, by an additive process, such as 3-D printing or deposition, or by deformation, such as bending in a press brake. Machine tools can be locally or remotely controlled by a human, can be controlled by a stored computer program, or can be autonomous. Non-limiting examples of machine tools to which the disclosed technologies can be applied include 3-D printers, broaches, drills, grinders, laser cutters, lathes, mills, planers, press brakes, or shapers.

The term “measurement” refers to the act of obtaining a value of a physical quantity, or the value thereby obtained.

A “metric” is a function providing a single value from one or more data entities. To illustrate, a metric can be an rms (root-mean-square) tracking error derived from deviations between a predicted trajectory and a desired trajectory over a range of sample times. Another metric can be a product or a weighted sum of the rms tracking error and a measure of smoothness of a candidate system input. In examples, varying parameters of a kernel function (or selecting a different kernel function) can lead to different values of the metric. Accordingly, kernels or kernel parameters can be chosen to optimize a value of the metric. Some metric values disclosed herein are numerical (with or without units), but this is not a requirement, and other metric values can have e.g. logical or categorical values.

A “model” of a system is a mathematical function, formula, or other description that enables an output of the system to be predicted based on one or more inputs to the system and, in some cases, a state of the system.

Terms such as “optimum,” “best”, “extremum,” “lowest”, “maximum,” or the like are used to indicate that a selection among a few or among many alternatives can be made, and such selections need not be lower, better, less, or otherwise preferable to other alternatives not considered.

A “parameter” is a quantity that can have a particular “value.” The term parameter does not include independent variable(s), such as time, over which a dynamical system can evolve. Some parameters of interest herein define particular instances of a kernel function. While parameters often have numerical values, this is not a requirement, and some parameter values can be logical values, strings, or data structures.

Following Bayesian terminology, “prior” refers to probabilities absent imposition of some information, and “posterior” refers to probabilities taking into account that information, e.g. specification of a desired trajectory.

“Smoothness” is numerical attribute of a characteristic that is inversely related to variations of the characteristic, its first derivative, or one or more other derivatives, over one or more independent variables. To illustrate, a straight line has a constant first derivative and can have a high smoothness value. A square wave has a first derivative which varies between plus and minus infinity and is discontinuous. The square wave can have a lower value of smoothness than a sine wave whose first derivative varies continuously over a finite range. A smooth system input can be desirable for having lower power requirement than a less smooth input.

A “stepper motor” is a motor whose shaft has a discrete set of stable angular positions. A stepper motor can operate in pulsed mode, where one drive pulse causes the shaft to shift from one stable position to an adjacent stable position. However, this is not a requirement, and some stepper motors can also operate in a continuous mode.

A “trajectory” is a specification of a system output over a range of one or more independent variables. To illustrate, the system output can be a vehicle position and a sole independent variable can be time, but these are not requirements, and other system outputs and other independent variables can be used. System output can be scalar, vector, or another form of data structure. The independent variable can be a scalar (e.g. time) or multi-dimensional (e.g. having two or three spatial dimensions). A trajectory can be organized as a collection of segments, two of which can be overlapping (e.g. having multiple sample times in common), abutting (e.g. a last sample time of one segment is a first sample time of another segment) or adjacent (e.g. the last sample time of one segment and the first sample time of the other segment are consecutive but distinct sample times). An “initial” segment among a group of segments has the earliest starting time, where the independent variable is time, or an extremum position where other independent variable(s) are used. In this disclosure, segments are sometimes indexed by an index variable (e.g. “i”). Subscripts and parenthetical notation for index variables are used interchangeably.

A “vehicle” is a machine configured to transport people or goods. Vehicles can operate on or in one or more media such as land (with or without roads, or underground), sea, air, or space. Vehicles can be locally or remotely controlled by a human, can be controlled by a stored computer program, or can be autonomous. Non-limiting examples of vehicles to which disclosed technologies can be applied include: cars, trucks, trains, boats, planes, drones, or robots. For example, given a desired trajectory, disclosed technologies can be applied to determine an optimum drive profile, which can be applied to the vehicle.

### Example System Operations

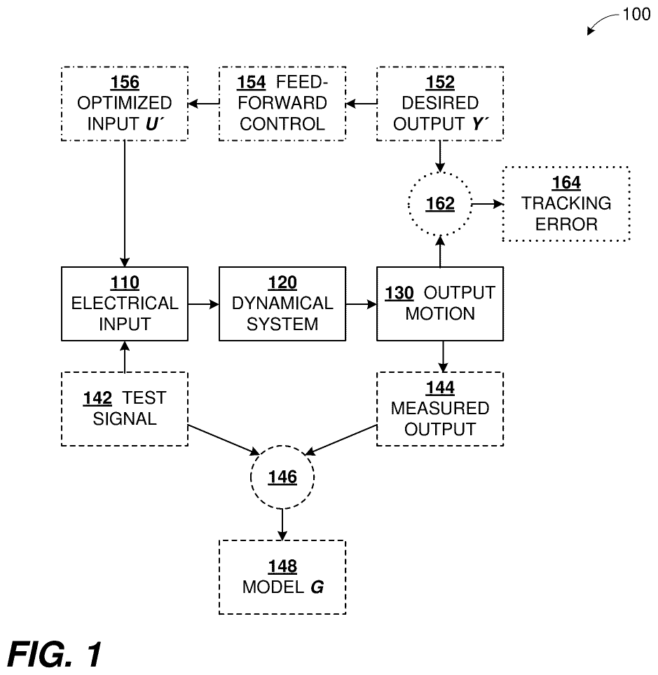

FIG. 1 is a diagram 100 of example operations on a dynamical system. FIG. 1 is used to explain basic operation of a system, determination of a system model, feedforward control of the system, and monitoring of tracking error.

Initially, a dynamical system 120 can receive an input 110 and produce a responsive output 130. Illustratively, input 110 can be an electrical signal and output 130 can be an output motion, but these are not requirements. Illustratively, system 120 can be a motion control system, but this is not a requirement. Motion control systems can variously encompass 3-D printers or other machine tools; robots; manned, unmanned, or autonomous vehicles; or other machinery.

Dashed outline blocks 142-148 illustrate determination of a system model. Test signal 142 can be applied as input 110, and output 130 can be measured to obtain measured output 144. Measured output 144 and test signal 142 can be analyzed at process block 146 to determine model G 148. Illustratively, test signal 142 can be a swept sine signal, and a complex ratio of measured output 144 to test signal 142 can provide a complex transfer function (as a function of frequency) in tabular form. Poles and zeros of the transfer function can be determined, e.g. by fitting or other regression analysis, to express model G in polynomial form.

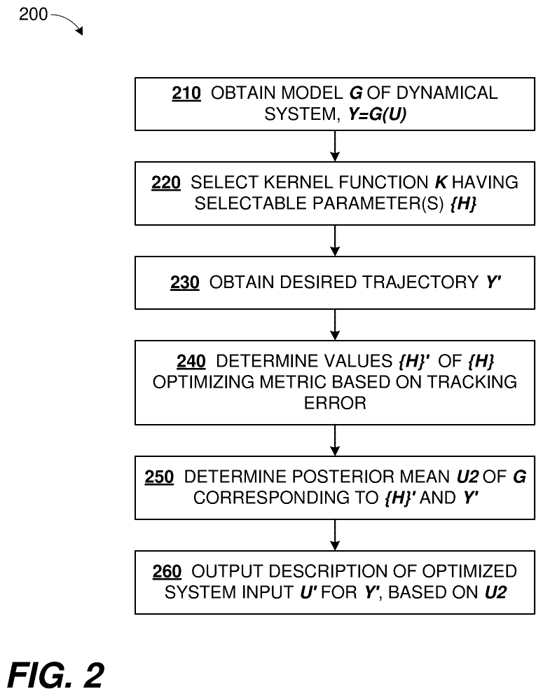

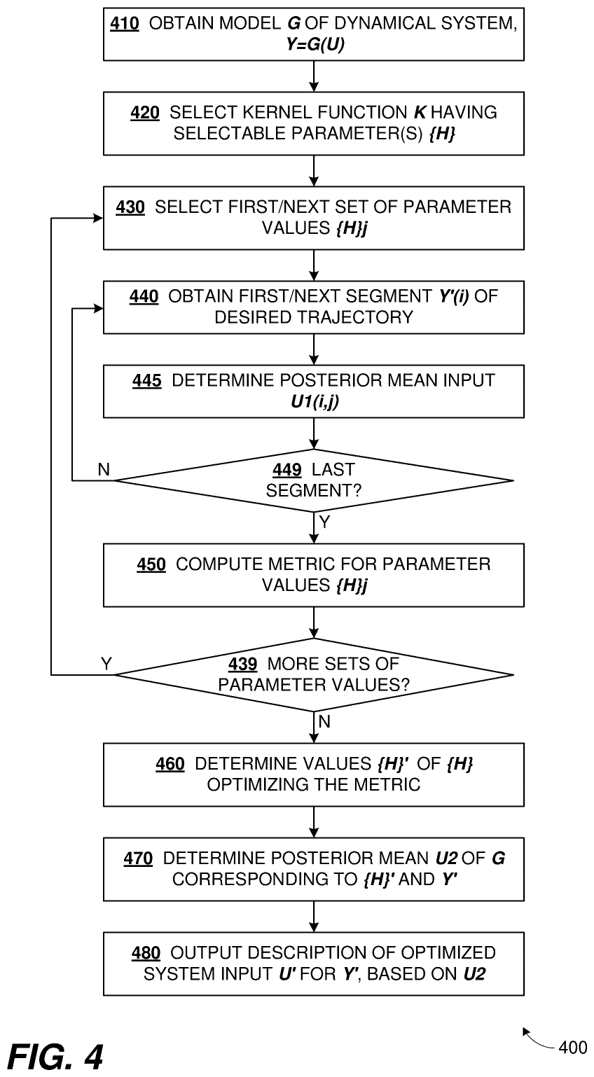

Dash-dot outline blocks 152-156 illustrate feedforward control of system 120 for desired output Y′ 152. Feedforward control analysis for Y′ 152 can be performed at block 154 to obtain an optimum input U′ 156. A Gaussian process technique can be used at block 154, similar to that described below in context of FIG. 2 or FIG. 4, or an extension or variation thereof. Optimized input U′ 156 can be applied as input 110 to system 120 to produce output 130, which can match desired output Y′ 152 to within a predetermined tolerance.

Dotted outline blocks 162-164 illustrate determination of tracking error. Desired output Y′ 152 and actual output 130 can be compared at block 162. The comparison can include calculation of an instantaneous difference between desired output Y′ 152 and actual output 130, from which an rms variation between desired output Y′ 152 and actual output 130 can be calculated. Tracking error 164 can be presented as a time-varying function or as a scalar quantity such as rms variation over time. A scalar tracking error 164 can be suitable for comparison between values of kernel parameters {H} so as to find optimum values thereof, or for comparison between kernel functions K, to determine an optimum kernel function.

### First Example Method

FIG. 2 is a flowchart 200 of a first example method according to the disclosed technologies. In this method, a Gaussian process is used to derive an optimized system control input for a desired system output trajectory.

At process block 210, a model G of a dynamical system can be obtained. Model G can define a transfer function of the system, which can be applied to a description U of the system input to obtain a prediction Y of the system output, according to the equation Y=G (U). The system input can be represented as a Gaussian process having a zero mean and a covariance matrix. In some examples, model G can be represented as a triangular matrix G1 shown in Equation (0.1), whose non-zero coefficients are derived by transforming system model G(z) to the time domain, thus g(j)=IFFT(G(z)) evaluated at sample j. E is the total number of sample points.

$$G 1 = [ \begin{matrix}g ( 0 ) & 0 & … & 0 \\ g ( 1 ) & g ( 0 ) & … & 0 \\ ⋮ & ⋮ & ⋱ & ⋮ \\ g ( E ) & g ( E - 1 ) & … & g ( 0 )\end{matrix} ] \qquad ( 0.1 )$$

At block 220, a kernel function K can be selected having one or more selectable parameters {H}. Kernel function K can impose a prior probability distribution on the covariance matrix of the system input.

At block 230, a desired trajectory Y′ of the system can be obtained. A posterior mean (not yet determined) of the Gaussian process can be a description U1 of a candidate system input and can be dependent on kernel function K (including selectable parameters {H}), model G, and desired trajectory Y. Formally, input U1 can be denoted U1 (i; {H}, G, Y′). That is, candidate system input U1 for each sample point i (e.g. at respective times) can depend on parameters {H}, model G, and desired trajectory Y′.

At block 240, values {H}′ of selectable parameters {H} can be determined which optimize a predetermined metric. The metric can depend at least in part on a tracking error such as ∥Y′−G(U1)∥.

At block 250, the posterior mean U2 corresponding to {H}′ can be determined, e.g. U2=U1(t; {H}′, G, Y′) and at block 260, an optimized system input U′ can be outputted based on U2.

Numerous variations and extensions can be implemented within scope of the disclosed technologies. In some examples, model G can be obtained at block 210 by performing measurements on the system. To illustrate, a swept sinusoidal input can be applied to the system, and the output can be measured to directly obtain gain and phase shift of the system as a function of frequency. That is, model G can be obtained based on results of the measurements. In other examples, model G can be derived from the physics of the system, from published parameters of system components. Model G can also be stored in computer-readable media, and can be retrieved from such media at block 210.

In further examples, optimized system input U′ can be applied to the dynamical system, to obtain the desired trajectory Y′ or a close approximation thereof. The desired trajectory can include physical coordinates, derived coordinates, phase space coordinates, or hidden coordinates, which can be a function of time or another independent variable. The trajectory can include scalar or vector coordinates, or another data structure of coordinates.

Block 240 can be performed by evaluating U1 for each of multiple sets of parameter values {H}, and using U1 to calculate the respective predetermined metric. The predetermined metric used at block 240 can depend on smoothness of U1. To illustrate, an input Ula having small root-mean-square variation in U1, dU1/dt, or another derivative, can be preferred over another input U1b having a larger corresponding root-mean-square variation. Optimization of the metric can be performed by various techniques. Non-limiting examples of such techniques include grid search over the parameters {H}, bisection search, gradient descent, steepest descent, genetic algorithms, or annealing. The search space can be limited to regions where the posterior mean converges to a stable input signal.

In certain examples, the method can be extended to determining whether the optimum value of the metric optimized at block 240 satisfies a predetermined criterion. Block 260 can be performed in response to determining that the predetermined criterion is satisfied. If the predetermined criterion is not satisfied, blocks 220 and 240 can be repeated with a different kernel function.

Multiple iterations of blocks 220 and 240 can be performed with respective selected kernel functions. Blocks 250 and 260 can be performed for a particular one of the kernel functions having a best value of the optimized metric.

The system input can be a time-varying electrical signal. Illustratively, the system input can be a stepper motor drive signal.

### First Example Demonstration

In this section, an example of the first method is worked out. In this example, a time interval T of interest has E sample points indexed from 1 to E. System input U and desired output Y′ are each represented as an E dimensional column vector. System input U is modeled as a Gaussian process N defined by its (prior) mean A, taken to be zero over T, and a symmetric positive definite E×E covariance matrix K whose elements represent the covariance between U values at respective pairs of sample points. That is, K is the covariance of U·U^{T}. Covariance matrix K can in turn depend on a set of parameters {H}, one of which can be an overall multiplicative scaling factor λ, thus K=λ·K0. Equation (1.1) shows the probability distribution of U according to this Gaussian process.

$$p ( U ) = N ( A = 0 , K ( \{ H \} ) = λ \cdot K 0 ) \qquad ( 1.1 )$$

In this example, output Y is linearly dependent on input U via model G, but may also incorporate some uncorrelated noise S, Y=G1·U+S. S can also be represented as a Gaussian process with zero mean, variance σ² at each sample point, and covariance zero between distinct sample points. Equation (1.2) shows the probability distribution of noise S, where I is the E×E identity matrix.

$$p ( S ) = N ( 0 , {σ}^{2} \cdot I ) \qquad ( 1.2 )$$

Because Y is linearly dependent on zero-mean Gaussian processes U and S, Y is also a zero-mean Gaussian process, whose covariance matrix can be derived from the covariance matrices of U and S. Thus cov(Y·Y^{T})=cov((G1·U+S)·(U^{T}·G1^{T}+S^{T}))=G1·cov(U·U^{T})·G1^{T}+cov(S·S^{T})+G1·cov(U·S^{T})+cov(S·U^{T})·G1^{T}. Because cov(U·U^{T})=K, cov(S·S^{T})=σ²·I, and the cross terms between U and S have zero covariance, this can be simplified to cov(Y·Y^{T})=G1·K·G1^{T}+σ²·I. The probability distribution p(Y) can be written as shown in Equation (1.3).

$$p ( Y ) = N ( 0 , G 1 \cdot K \cdot G {1}^{T} + {σ}^{2} \cdot I ) \qquad ( 1.3 )$$

Then, U and Y can be concatenated into a column vector of length 2·E, which is also a zero-mean Gaussian process. New cross terms between Y and U include cov(Y·U^{T})=G1·K and its transpose. Equation (4) shows the concatenated process.

Y can be set to a desired trajectory Y′ in Equation (1.4) to obtain conditional probability p(Y′|U). p(U) is defined in Equation (1) and Bayes' theorem can be applied to determine p(U|Y′). The remaining term p(Y) can be taken from Equation (1.3) or can be incorporated implicitly through normalization of p(U|Y′). p(U|Y′) is also a Gaussian process as shown in Equation (1.5). Textbook analysis can be applied to derive the formulae for cov(U|Y′) and U1 in Equations (1.6), (1.7).

$$p ( [ \begin{matrix}Y \\ U\end{matrix} ] ) = N ( [ \begin{matrix}0 \\ 0\end{matrix} ] , [ \begin{matrix}cov ( Y \cdot {Y}^{T} ) & cov ( Y \cdot {U}^{T} ) \\ cov {( U \cdot {Y}^{T} )}^{T} & cov ( U \cdot {U}^{T} ) = K\end{matrix} ] ) \qquad ( 1.4 )$$

$$where$$

$$\begin{matrix}cov ( Y \cdot {U}^{T} ) = cov {( U \cdot {Y}^{T} )}^{T} = G 1 \cdot K \\ cov ( Y \cdot {Y}^{T} ) = G 1 \cdot K \cdot G {1}^{T} + {σ}^{2} \cdot I \\ p ( U \vert YD ) = N ( U 1 , cov ( U \vert YD ) )\end{matrix} \qquad ( 1.5 )$$

$$U 1 = {( \frac{G {1}^{T} \cdot G 1}{{σ}^{2}} + {K}^{- 1} )}^{- 1} \cdot ( \frac{G {1}^{T}}{{σ}^{2}} \cdot YD ) \qquad ( 1.6 )$$

$$cov ( U \vert YD ) = {( \frac{G {1}^{T} \cdot G 1}{{σ}^{2}} + {K}^{- 1} )}^{- 1} \qquad ( 1.7 )$$

### Comparative Example

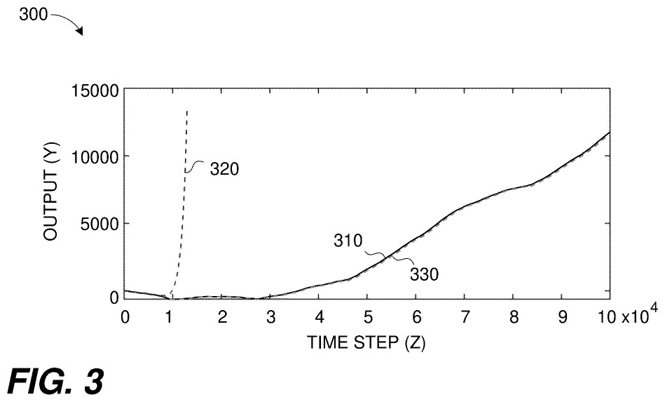

FIG. 3 is a chart 300 illustrating comparative advantage of an example of the disclosed technologies. Chart 300 shows three graphs of system outputs as a function of sample time. Initially, solid line graph 310 is a desired trajectory. Dashed line graph 320 illustrates system behavior using filtered basis functions (“FBF”), a conventional technique. The FBF output 320 tracks desired trajectory 310 initially, but diverges exponentially beginning before 10% of the total time range. In comparison, a Gaussian process method disclosed herein gives output 330 which tracks the desired trajectory within a predetermined tolerance, across the entire time range.

### Second Example Method

FIG. 4 is a flowchart 400 of a second example method in which Gaussian process and Bayes' theorem are recursively applied. This method can be an extension of the method of FIG. 2. Examples of optimization described herein rely on matrix inversion operations: for a sample trajectory of M sample points, computation scales as M³. By operating on windows of smaller M, a recursive method can significantly reduce the computation required for feedforward optimization.

At process block 410, a model G of a dynamical system can be obtained, similar to block 210 of FIG. 2. Model G can define a transfer function of the system, which can be applied to a description U of the system input to obtain a prediction Y of the system output, according to the equation Y=G (U). The system input can be represented as a Gaussian process having a zero mean and a covariance matrix.

At block 420, a kernel function K can be selected having one or more selectable parameters {H}, similar to block 220. Kernel function K can impose a prior probability distribution on the covariance matrix of the system input.

Block 430 is the top of a loop over values of the selectable parameters {H}. By iterating over multiple sets of parameter values, an optimum set {H}′ can be determined. At block 430, a j-th set of parameter values {H} j can be selected.

Block 440 is the top of a loop over trajectory segments, which can overlap. At block 440, an i-th segment Y′ᵢ of a desired trajectory Y′ can be obtained, similar to block 230. A posterior mean (not yet determined) of the Gaussian process can be a description U1ᵢ of a candidate system input and can be dependent on kernel function K (including selectable parameters {H}), model G, desired trajectory Y′ᵢ, and previously determined posterior input U1Pᵢ including, at least in part, posterior input of a preceding segment U1ᵢ₋₁. Formally, input U1 can be denoted U1ᵢ(t; {H}, G, Y′ᵢ, U1Pᵢ). That is, candidate system input U1ᵢ can be a function of time t, with dependence on parameters {H}, model G, desired trajectory Y′, and preceding input U1Pᵢ (including dependence on U1ᵢ₋₁). For the first segment (e.g. i=0), the preceding segments' input can be taken to be zero or any other initial value. To illustrate, U1P₀ can be set to a known initial position of a machine tool or vehicle.

At block 445, the posterior mean U1(i) can be determined for the i-th segment and the j-th set of parameter values. At decision block 449, a determination can be made whether the current segment is the last segment. If not, the method can follow the N branch back to block 440, i can be incremented (i←i+1) for the next segment, and blocks 440, 445 can be repeated for this next segment. Eventually, block 449 can determine that a last segment has been processed, and the method can follow the Y branch from block 449 to block 450.

At block 450, a metric can be computed for the current set of parameter values {H}ⱼ. The metric can depend at least in part on a tracking error such as ∥Y′−G(U1)∥, where U1 is a combination (e.g. a concatenation of respective parts) of U1(i).

At decision block 439, a determination can be made whether additional sets of parameter values are to be evaluated. In some examples, an exhaustive search of a predetermined collection of sets of parameter values can be made. In other examples, scanning of parameter values can be terminated based on a termination criterion. Exemplary termination criteria can be based on metric meeting or exceeding a predetermined target value, or the metric having converged to a stable optimum value to within a predetermined tolerance. If more sets of parameter values are to be analyzed, the method can follow the Y branch back to block 430, j can be incremented (j←j+1) for the next set of parameter values, and the blocks from 430 to 450 can be repeated for this next set of parameter values. Eventually, block 439 can determine that no more set of parameter values are to be analyzed, and the method can follow the N branch from block 439 to block 460.

At block 460, similar to block 240, values {H}′ of selectable parameters {H} can be determined which optimize the predetermined metric computed at block 450. At block 470, the posterior mean U2 corresponding to {H}′ can be determined, e.g. U2 (t; {H}′, G, Y′), similar to block 250. At block 480, optimized system input U′ can be outputted based on the posterior mean U2, similar to block 260.

Numerous variations and extensions can be implemented within scope of the disclosed technologies. In some examples, the segments can overlap. To illustrate, successive M point segments can slide by P sample points from one segment to the next. That is, Bayes' theorem can be applied over M sample points, but only the earliest P points are preserved in the overall system input U1. However, the last segment processed can have all M points retained in U1. M and P can be selected according to the dynamics of a particular system. Where a system is stable or sample points are very close to one another (relative to a characteristic frequency of the system) P can be fairly large. To illustrate, 64-sample segments (M=64) can slide by P=32 samples from one sample to the next. In other systems, where a system is close to instability (G having a zero just outside the unit circle), P can be kept small relative to M. To illustrate, 64-sample segments can slide by P=2 sample points.

As described herein, the computational burden of a Gaussian process optimization scales as M³. The number of segments to be analyzed scales as N/P, where N is the total trajectory length measured in sample points. To illustrate, for N=1024, an all-at-once analysis (e.g. just one segment; M=N=1024) incurs a computation cost of M³=2³⁰≈10⁹. Recursive analysis with M=32 and P=16 incurs a computation cost of M³·N/P=2²¹≈2·10⁶, 500 times lower than the single segment approach. With smaller overlap, e.g. M=32 and P=2, the computation cost M³·N/P=2²⁴≈1.6·10⁷ is still a factor of 60 lower than that of the single segment approach.

Additional variations and extensions can be similar to those described in context of FIG. 2 or elsewhere herein.

### Second Example Demonstration

In this section, a demonstration of the second method is worked out. In this demonstration, an overall time duration T is subdivided into a series of input segments, each of which is evaluated using the disclosed Gaussian process methodology. Evaluation of each segment is based not only on the desired trajectory for that segment, but also on an input from a preceding segment. Successive segments may overlap.

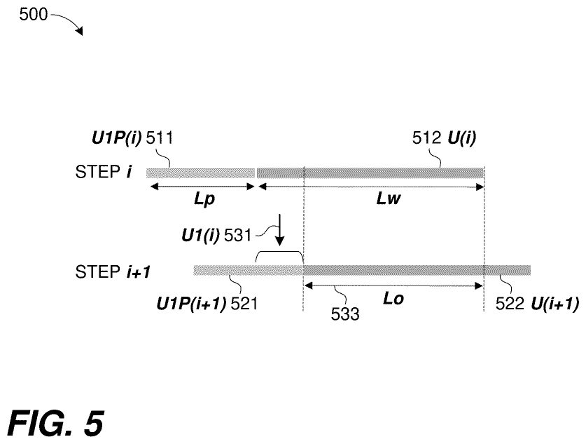

FIG. 5 is a diagram 500 illustrating segment-by-segment application of the disclosed technologies according to the second method. On an i^{th} iteration, step i, Gaussian process inversion can be applied to segment 512 U(i) using posterior input 511 U1P(i) from one or more earlier segments as a guide. On a next iteration, step i+1, Gaussian process inversion can be applied to segment 522 U(i+1) guided by posterior input 521 U1P(i+1). Posterior input 521 U1P (i+1) can include all or a portion of posterior input U1(i) 531 determined on the first iteration for segment 512, and can also include a portion common with segment 511 U1P (i). Segments 512, 522 overlap over range 533.

The formalism in this demonstration is an extension of that for the first method. At each iteration, Bayes' rule is applied to Lw sample points of a current segment based on corresponding Lw sample points of the desired trajectory, and also guided by Lp samples of previously determined input U1P as indicated by Equation (2.1). The next iteration can advance by P sample points (P=Lw−Lo).

$$U 1 ( i ) = f ( U 1 P ( i ) , {Y}^{′} ( i ) ) \qquad ( 2.1 )$$

For a given iteration, previous and current samples can be concatenated as a zero-mean Gaussian process with covariance matrix K, as shown in Equation (2.2). K can be formed by aggregating components K1, K2, K3 as shown in Equation (2.3). K1 is the Lp×Lp covariance matrix for the Lp previous input samples, K3 is the Lw×Lw covariance matrix for the Lw current input samples, and K2 is a Lp×Lw covariance matrix between respective pairs of previous and current input samples. The desired trajectory can be expressed in terms of the system model G(z), as shown in Equation (2.4), where G2 is a diagonal band matrix shown in Equation (2.5), and the non-zero coefficients are derived by transforming system model G(z) to the time domain, thus g(j)=IFFT(G(z)) evaluated at sample j.

$$p ( [ \begin{matrix}U 1 P ( i ) \\ U ( i )\end{matrix} ] ) = N ( [ \begin{matrix}0 \\ 0\end{matrix} ] , λ \cdot K ( i ) ) \qquad ( 2.2 )$$

$$K ( i ) = [ \begin{matrix}K 1 & K 2 \\ K {2}^{T} & K 3\end{matrix} ] \qquad ( 2.3 )$$

$$Y ( i ) = G 2 \cdot [ \begin{matrix}U 1 P ( i ) \\ U ( i )\end{matrix} ] + S ( i ) \qquad ( 2.4 )$$

$$G 2 = [ \begin{matrix}g ( H ) & … & 0 & … & … & … & 0 \\ ⋮ & ⋮ & ⋮ & ⋮ & ⋮ & ⋮ & ⋮ \\ … & g ( H ) & … & g ( 1 ) & g ( 0 ) & 0 & 0 \\ … & … & g ( H ) & … & g ( 1 ) & g ( 0 ) & 0 \\ … & … & … & g ( H ) & … & g ( 1 ) & g ( 0 )\end{matrix} ] \qquad ( 2.5 )$$

Similar to Equation (1.4), output and input vectors can be concatenated. The resulting column vector has length 2Lw+Lp and a probability distribution represented by Equation (2.6). The covariance terms in Equation (2.6) are defined in Equations (2.7)-(2.9).

$$p ( [ \begin{matrix}U ( i ) \\ U 1 P ( i ) \\ Y ( i )\end{matrix} ] ) = N ( [ \begin{matrix}0 \\ 0 \\ 0\end{matrix} ] , λ \cdot [ \begin{matrix}Σ 1 & Σ 2 \\ Σ {2}^{T} & Σ 3\end{matrix} ] ) \qquad ( 2.6 )$$

$$where$$

$$Σ1 = K 3 \qquad ( 2.7 )$$

$$Σ 2 = [ \begin{matrix}K 2 & [ K 2 & K 3 ] \cdot G {2}^{T} ]\end{matrix} \qquad ( 2.8 )$$

$$Σ 3 = [ \begin{matrix}K 1 & \begin{matrix}[ K 1 & K 2 ] \cdot G {1}^{T}\end{matrix} \\ \begin{matrix}G 2 \cdot [ K 1 & {K 2 ]}^{T}\end{matrix} & G 2 \cdot K ( i ) \cdot G {2}^{T} + \frac{{σ}^{2}}{λ} \cdot I\end{matrix} ] \qquad ( 2.9 )$$

Then, Y can be set to Y′ᵢ to obtain conditional probability p(Y′ᵢ|Uᵢ, U1Pᵢ). p(Uᵢ, U1Pᵢ) is defined in Equation (2.2), and Bayes' theorem can be applied to determine p(Uᵢ|U1Pᵢ, Y′ᵢ) expressed as Equation (2.10). The desired mean U1ᵢ can be determined according to Equation (2.11) and the correspondence covariance matrix can be determined according to Equation (2.12).

$$p ( U ( i ) \vert [ \begin{matrix}U 1 P ( i ) \\ {Y}^{′} ( i )\end{matrix} ] ) = N ( U 1 ( i ) , cov ( U ( i ) \vert [ \begin{matrix}U 1 P ( i ) \\ {Y}^{′} ( i )\end{matrix} ] ) ) \qquad ( 2.1 )$$

$$U 1 ( i ) = Σ 2 \cdot Σ {3}^{- 1} \cdot [ \begin{matrix}U 1 P ( i ) \\ {Y}^{′} ( i )\end{matrix} ] \qquad ( 2.11 )$$

$$cov ( U ( i ) \vert [ \begin{matrix}U 1 P ( i ) \\ {Y}^{′} ( i )\end{matrix} ] ) = λ \cdot ( Σ 1 - Σ 2 \cdot Σ {3}^{- 1} \cdot Σ {2}^{T} ) \qquad ( 2.12 )$$

The analysis can be repeated for successive segments with some overlap as described in context of FIG. 5, to build a complete system input for an entire time duration T. A metric can be evaluated over the entire time duration T, and parameters of covariance kernel function K can be varied to optimize this metric.

### Example Machine Tool Environment

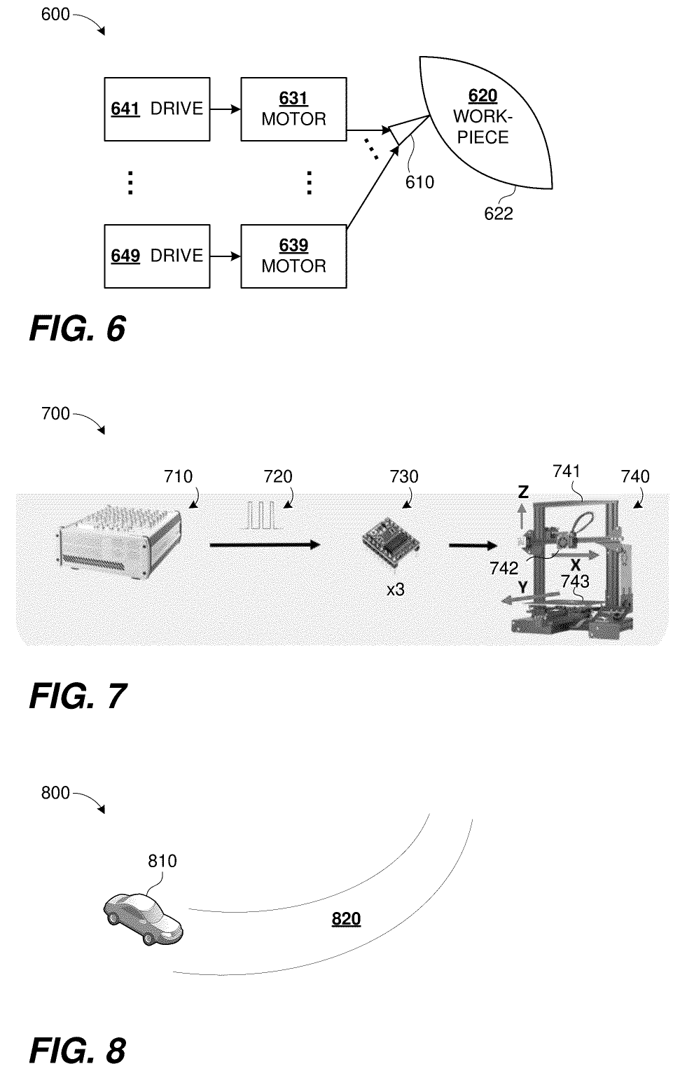

FIG. 6 is a diagram 600 of an example machine tool environment in which disclosed technologies can be employed. Tool tip 610 can operate on workpiece 620 having desired surface contour 622. Tool tip 610 can have multiple motors 631 . . . 639 controlling respective degrees of freedom, e.g. for translation or orientation. Each motor 631 . . . 639 can have operation controlled by respective drive 641 . . . 649.

Desired trajectories of tool 610 (e.g. one trajectory for each degree of freedom) can be derived from desired contour 622, along with other optional parameters such as cutting speed or cutting depth. Gaussian process optimization as disclosed herein can be applied to determine optimum drive signals for drives 641 . . . 649 to achieve the desired trajectories.

In variations, and because motion is relative, one or more of motors 631 . . . 639 can be applied to control the position or orientation of workpiece 620 rather than tool 610. For examples, motors can be coupled to a table of a milling machine, or another type of stage on which workpiece 620 is mounted.

### Example 3-D Printer Environment

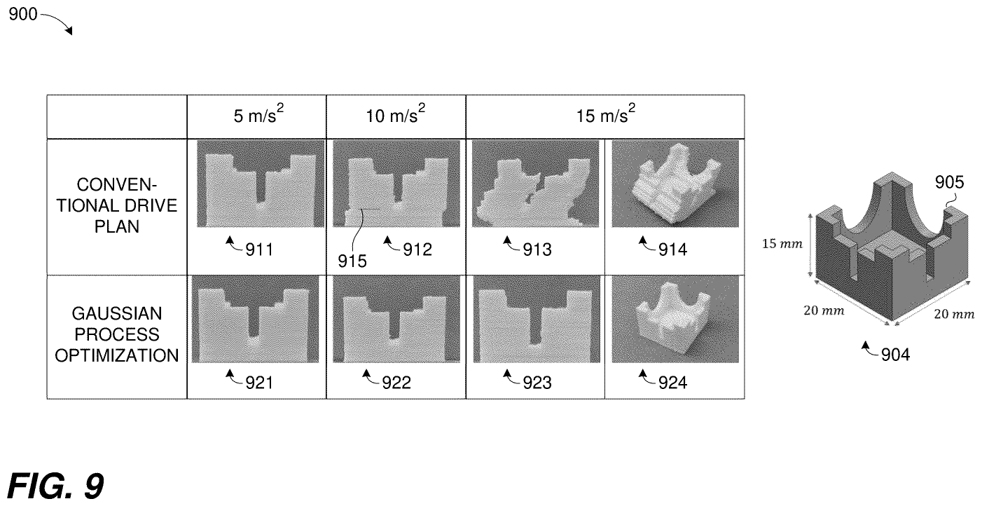

As a particular instance of a machine tool, FIG. 7 is a diagram 700 of an example 3-D printer environment. The illustrated 3-D printer 740 is a model Ender 3 V2 fused deposition tool manufactured by Shenzhen Creality 3D Technology Co., Ltd., Shenzhen, China. Fused deposition print head 742 can be translated in X and Z directions in a plane of frame 741, above work table 743 upon which a workpiece (not shown) can be fabricated. Table 743 can also be translated in the Y direction as shown. The three degrees of freedom can be exercised by respective stepper motors which are part of 3-D printer 740.

3-channel driver 705 includes a MicroLabBox signal generator (dSpace GmbH, Paderborn, Germany) which can generate programmable pulse streams 720 for each of the three motion control channels (X, Y, Z), and three DRV8825 stepper motor drive modules (Texas Instruments, Dallas, TX) which can amplify pulse streams 720 to drive respective stepper motors of 3-D printer 740.

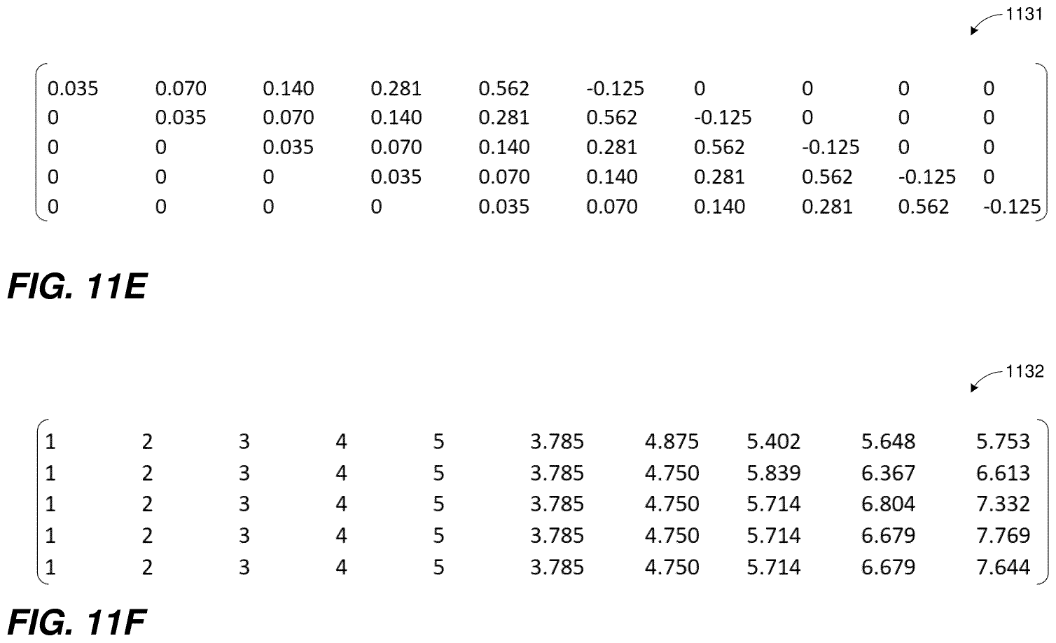

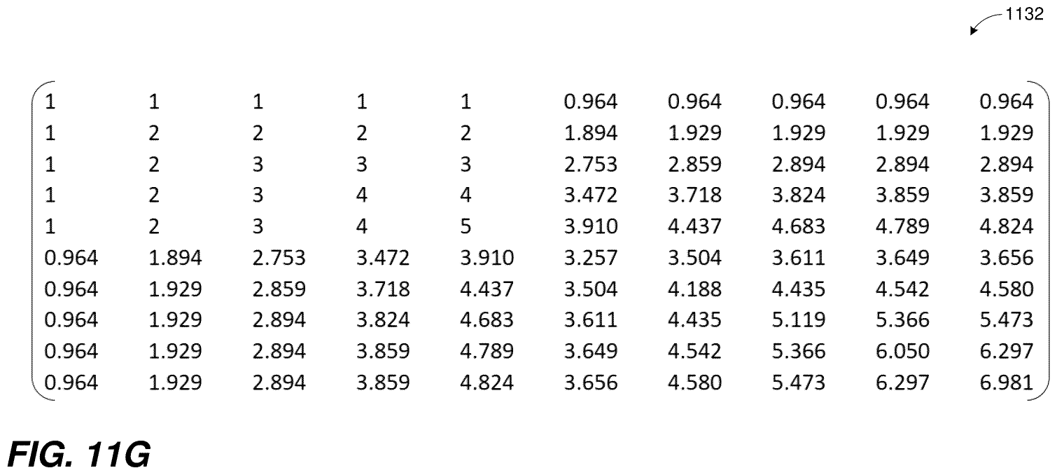

To illustrate, pulse streams 720 of varying frequency can be provided to each stepper motor to determine a system model G(z) for each respective degree of freedom of printer 740 as described in context of FIG. 10. A deposition plan can be prepared for a desired workpiece to be fabricated, and a desired trajectory can be derived from the deposition plan. As described in context of FIG. 2, FIG. 4, or elsewhere herein, an innovative Gaussian process technique can be used to derive optimized input drive signals for one or more of tool 740's stepper motors, so as to achieve the desired trajectory for tool 740, and ultimately a desired workpiece shape.

As described in context of FIG. 10 below, a system can exhibit strong response at certain frequencies. Peaked response can, in some instances, be associated with vibration instability. For a stepper motor, this can mean losing accurate step count—e.g. taking two steps in response to a single pulse—which can lead to severe departures from an intended trajectory.

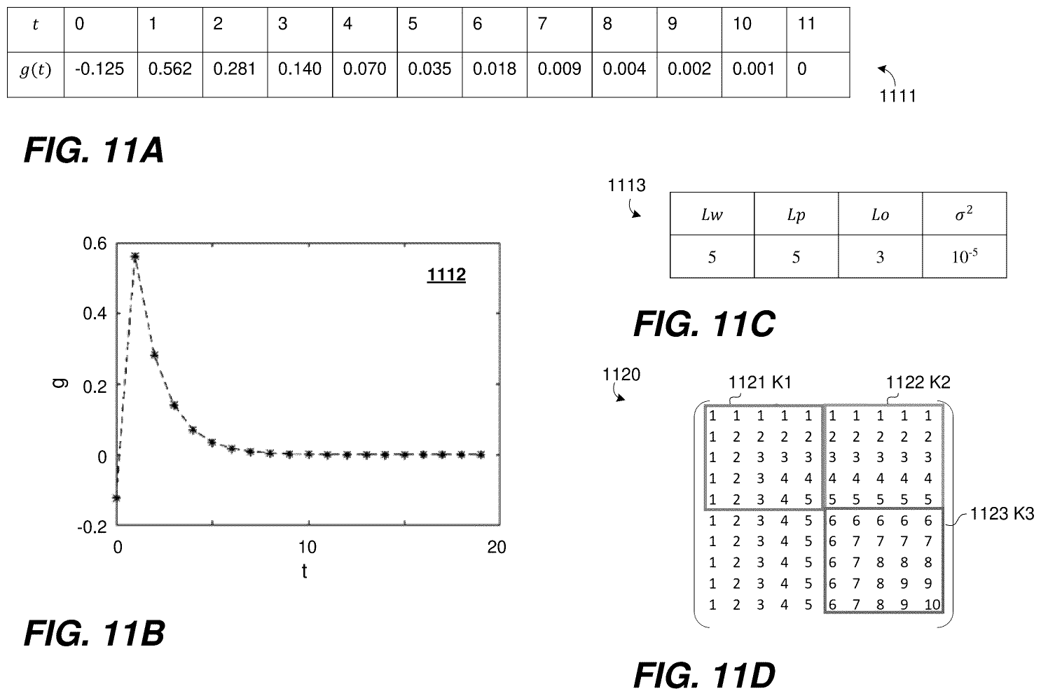

FIG. 9 is a drawing 900 containing a set of images 911-914, 921-924 demonstrating superior performance of disclosed technologies in the face of excessive vibration. Initially, inset 904 is an oblique view drawing of a desired workpiece 905 to be fabricated using a 3-D printer similar to 740 of FIG. 7. In a series of experiments, printer 740 was programmed to fabricate the workpiece with and without using the disclosed Gaussian process technique, and at different machining speeds. Generally, increased machining speed can be desirable to reduce fabrication time, allowing printer 740 to be used for other projects. However, at increased speeds, stepper motors can have increased instances of skipping counts, e.g. due to excessive vibrations.

Images 911-913, 921-923 are elevation views organized in rows by feedforward planning technique and in columns according to peak acceleration. Image 911 shows a work product manufactured slowly, with a peak acceleration of 5 ms⁻², using a conventional drive program. The workpiece matches desired workpiece 905 to within expected performance of the tool. The drive program was sped up to have a peak acceleration of 10 ms⁻², and the resulting product is shown in image 912. Although image 912 can be recognized as workpiece 905, there is a noticeable transverse discontinuity as the tool loses positional accuracy at a height approximately indicated by marker 915. Further speedup of the drive program, to a peak acceleration of 15 ms⁻², results in a product shown in image 913. This product shows effects of numerous errors in step counting, and is barely recognizable. Image 914 is an oblique view of the same product as image 913.

Applying the disclosed Gaussian process optimization, three products were fabricated with peak acceleration speeds of 5, 10, and 15 ms⁻². Elevation views of the resulting products are shown in images 921-923, with image 924 being an oblique view corresponding to elevation view 923. Although some evidence of increased edge roughness can be seen as printing speed is increased, the Gaussian process optimization completely eliminates the loss of position information apparent in images 912-913. That is, the disclosed innovations can compensate for increased vibrations to avoid losing track of tool position.

The products of images 921-924 all match desired workpiece 905 to within expected performance of the 3-D printer. Feedforward control through Gaussian process optimization allows accurate tool operation at higher speeds than comparative techniques.

### Example Vehicle Environment

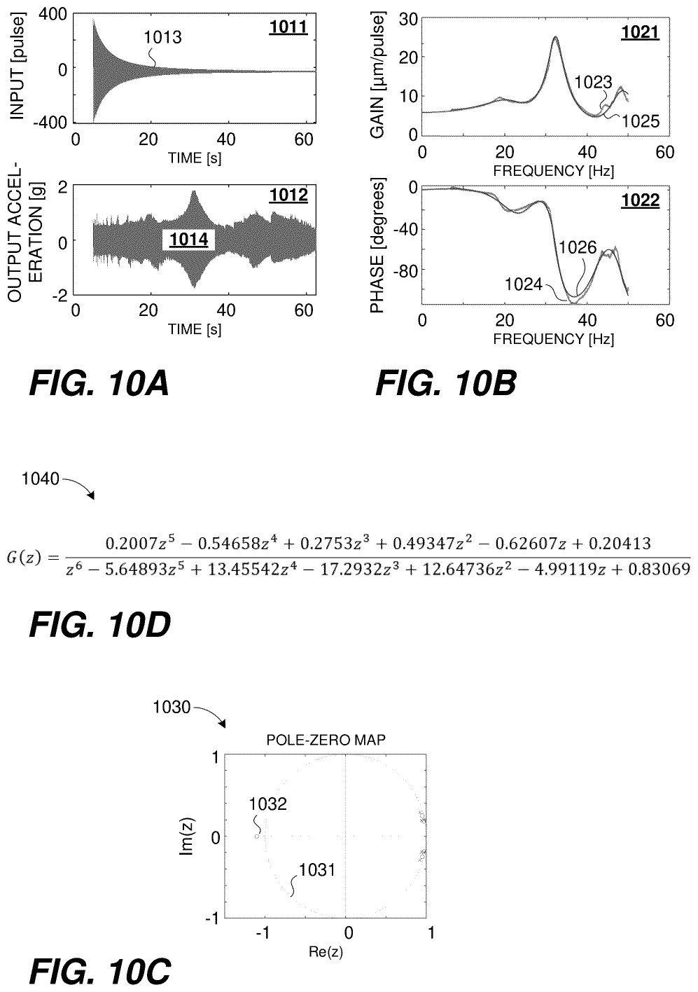

FIG. 8 is a diagram 800 of an example vehicle environment in which disclosed technologies can be employed. Vehicle 810 can be driven along road 820. That is, a desired trajectory can be derived based on following road 820, along with other optional parameters such as desired speed. Feedforward optimization as described herein can be used to determine optimum drive parameters (e.g. propulsion parameters or steering) to achieve the desired trajectory.

The vehicle environment can have a non-stationary model, as the input-output transfer function G can be dependent on gradient of road 820 (e.g. ascending or descending), or transverse banking. Moreover G can include effects of wind resistance, which can be dependent on an instantaneous speed of vehicle 810.

The vehicle environment can also require adaptive optimization, as the desired trajectory can evolve with time, e.g. to avoid obstacles such as other vehicles. Adaptive optimization can be addressed by use of a recursive optimization such as described in context of FIG. 4.

### Example Model Determination

FIG. 10A-10C are charts illustrating an example of model extraction which can be used with the disclosed technologies. FIG. 10D shows a representation of the model determined in FIG. 10B, as a ratio of two polynomials.

Starting with FIG. 10A, chart 1011 shows graph 1013 of input amplitude as a function of time, which can be applied to a dynamical system in order to extract a model for that system. Illustratively, graph 1013 can be a swept sine excitation (sometimes known as a chirp) having monotonically varying frequency as a function of time. In graph 1013, frequency is increasing with time. As illustrated, amplitude can vary inversely with frequency. Peak first or second derivative of the input amplitude can be maintained approximately constant as frequency changes.

Chart 1012 shows measured output 1014 of the system. Because excitation frequency of input 1013 is known as a function of time, measured output 1014 can be directly converted to system gain as a function of frequency. By comparing phase of output 1014 with phase of input 1013, the phase response of the system as a function of frequency can also be readily determined.

Turning to FIG. 10B, charts 1021-1022 show the measured gain response 1023 and measured phase response 1024 of the system, as a function of frequency, determined from graphs 1013-1014 of FIG. 10A. A system can exhibit strong response at certain frequencies (e.g. at about 32 s in chart 1012, corresponding to about 32 Hz in chart 1021). These peaks in response can, in some instances, be associated with excessive vibrations.

The gain and phase can be regarded as real and imaginary parts of a complex transfer function, which can be fitted to a rational function of sample interval z. Graphs 1025, 1026 respectively show the real (gain) and imaginary (phase) parts of the fitted function. FIG. 10D shows the fitted function G(z) 1040 modeling the instant dynamical system as a rational function, e.g. a ratio of two polynomials.

Factorization of the numerator and denominator of function 1040 yields the poles (roots of the denominator of G(z)) and zeroes (roots of the numerator) of rational function G(z) 1040. FIG. 10C is a chart 1030 showing poles (represented as “X”) and zeroes (represented as “O”) of G(z) 1040, in the complex z plane. Notably, zero 1032 is close to and outside unit circle 1031, which can be challenging for conventional feedforward techniques.

### Third Example Demonstration

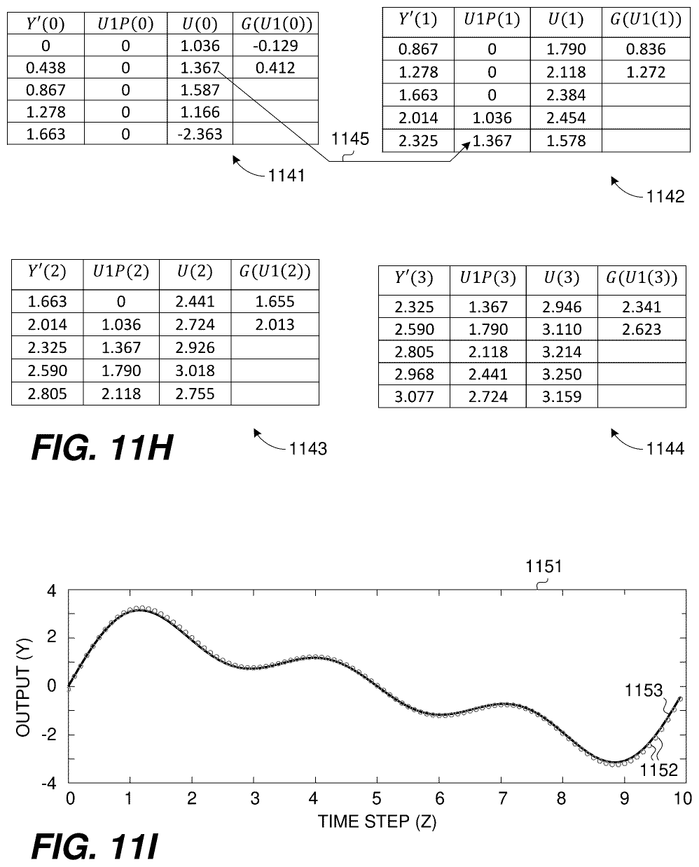

This example demonstrates detailed computations for recursively applying a disclosed feedforward optimization technique to a non-minimum phase (NMP) dynamical system and is described with reference to supporting diagrams and tables in FIGS. 11A-11M.

Equation (3.1) describes a desired output trajectory:

$$\begin{matrix}{y}_{d} = 2 sin ( 20 π kT ) + sin ( 40 π kT ) + sin ( 60 π kT ) , where \\ \begin{matrix}k = 0 , 1 , 2 , … , 100 , & T = 1 ms\end{matrix}\end{matrix} \qquad ( 3.1 )$$

k is a discrete time variable and Tis a spacing between successive sample points. An optimal input sequence for this trajectory is sought for a system whose transfer function is modeled by Equation (3.2):

$$G ( z ) = \frac{- 0.125 ( z - 5 )}{z - 0.5} \qquad ( 3 .. 2 )$$

This system has an NMP zero at 5. The impulse response of this transfer function in the discrete-time domain can be found by taking the inverse Z transform, G(z)→g (t) where t is a discrete time variable. Alternatively, the impulse response can be obtained by treating z as the delay operator and turning the transfer function into an autoregressive with exogenous output (ARX) model. FIGS. 11A-11B show the evaluated impulse response of the system in tabular and graphical forms 1111, 1112 respectively. There are only 11 significant elements in the impulse response.

The entire desired trajectory is subdivided into segments having Lw samples each. The segment length Lw can be selected according to the number of significant elements in the impulse response function (in this example, 11). To illustrate, Lw can be set to be within a factor of 1.1, 1.2, 1.5, 2, or 3 of the length of the impulse response. Here, for convenience of illustration, Lw has been set to five. Other parameters include: an overlap of Lo=3 samples between consecutive segments; a vector of Lp=5 previously determined sample inputs as a constraint on Bayesian analysis of the current segment; and a noise variance σ²=10⁻⁵. These parameters are shown as table 1113 in FIG. 11C.

A linear spline kernel Kernel(i, j)=min(i, j) is used to define the (prior) input covariance. The corresponding covariance matrix K of Equation (2.3) is shown in FIG. 11D. The diagonal quadrants 1121, 1123 correspond to K1 and K3 respectively, while off-diagonal quadrant 1122 corresponds to K2.

Matrix G2 1131 can be constructed from impulse response 1111 of FIG. 11A according to Equation (2.5), and is shown in FIG. 11E. Matrices Σ2 1132, Σ3 1133 can be computed according to Equations (2.8), (2.9) respectively, and are shown in FIGS. 11F, 11G.

Then, equation (2.11) can be applied recursively to successive segments i. Tables 1141-1144 in FIG. 11H show the calculations for the first four segments. For the first segment (i=0, table 1141), the previous input vector U1P(0) is a vector with all zeroes as the input before the start. G(U1(i)) is the output of the system using the input U1(i) that is obtained using the algorithm. At each segment, the first 2 elements (Lw−Lo=2) of U1(i) are retained as the most recent elements of U1P for the next segment, as indicated by arrow 1145.

Eventually, the end of the trajectory is reached at about 100 sample points (i=100). Chart 1151 of FIG. 11I shows the predicted output 1152 G(U′) (open circles) for the optimized input U′ overlaid on the desired trajectory Y′ 1153 (solid line). The predicted output matches the desired output over the entire timespan.

### ADDITIONAL EXAMPLES

The following are additional examples of the disclosed technologies.

Example 1 is a method, including: (a) obtaining a model of a dynamical system which generates a system output responsive to a system input, wherein the model is configured to receive a description of the system input and produce a corresponding prediction of the system output; for a Gaussian process representation of the system input having a mean and a covariance matrix: (b) selecting a kernel function, having one or more selectable parameters, to impose a prior probability distribution on the covariance matrix of the system input; (c) obtaining a desired trajectory of the system output; wherein a posterior mean of the system input, which is predicted to lead to the desired trajectory, is dependent on the kernel function, the model, and the desired trajectory of the system output; (d) determining respective value(s) of the one or more selectable parameters which optimize a predetermined metric based at least partly on a tracking error between the desired trajectory and the system output; and (e) determining the posterior mean of the Gaussian process corresponding to the determined parameter values and the desired trajectory; and (f) outputting a description of optimized system input for the desired trajectory based on the determined posterior mean.

Example 2 includes the subject matter of Example 1, and further includes performing measurements on the dynamical system, wherein the obtaining is based on results of the measurements.

Example 3 includes the subject matter of any of Examples 1-2, and further includes applying the optimized system input to the dynamical system.

Example 4 includes the subject matter of any of Examples 1-3, and further specifies that the desired trajectory comprises a spatial coordinate as a function of time.

Example 5 includes the subject matter of any of Examples 1-4, and further includes: (d2) determining whether the optimized metric satisfies a predetermined criterion; wherein act (f) is performed responsive to determining, in at least a given instance, that the optimized metric satisfies the predetermined criterion.

Example 6 includes the subject matter of Example 5, and further includes: performing first and second iterations of acts (d) and (d2) with the selected kernel function being first and second kernel functions respectively; performing the second iteration responsive to determining on the first iteration that the optimized metric for the first kernel function does not satisfy the predetermined metric; and determining on the second iteration that the optimized metric for the second kernel function satisfies the predetermined metric.

Example 7 includes the subject matter of any of Examples 1-6, and further specifies that a composite trajectory comprises a series of overlapping segments, and the method further comprises: iterating act (c), each successive iteration having the desired trajectory being a successive segment of the series of overlapping segments; wherein, for each segment after an initial one of the segments, the posterior mean is further dependent on the determined posterior mean of one or more preceding ones of the segments; and wherein the optimized system input is dependent on the respective posterior means of all the overlapping segments.

Example 8 is one or more computer-readable media storing instructions which, when executed by one or more hardware processors, cause the one or more hardware processors to perform operations comprising: (a) obtaining a model of a dynamical system which generates a system output responsive to a system input, wherein the model is configured to receive a description of the system input and produce a corresponding prediction of the system output; for a Gaussian process representation of the system input having a mean and a covariance matrix: (b) selecting a kernel function, having one or more selectable parameters, to impose a prior probability distribution on the covariance matrix of the system input; (c) obtaining a desired trajectory of the system output; wherein a posterior mean of the system input, which is predicted to lead to the desired trajectory, is dependent on the kernel function, the model, and the desired trajectory of the system output; (d) determining respective value(s) of the one or more selectable parameters which optimize a predetermined metric based at least partly on a tracking error between the desired trajectory and the system output; and (e) determining the posterior mean of the Gaussian process corresponding to the determined parameter values and the desired trajectory; and (f) outputting a description of optimized system input for the desired trajectory based on the determined posterior mean.

Example 9 includes the subject matter of Example 8, and further specifies that the predetermined metric is further based at least partly on smoothness of the mean of the system input.

Example 10 includes the subject matter of any of Examples 8-9, and further specifies that the operations further comprise: performing multiple iterations of acts (b) and (d) with respective selected kernel functions; and performing the operations (e) and (f) for one of the kernel functions having a best value of the optimized metric.

Example 11 includes the subject matter of any of Examples 8-10, and further specifies that a composite trajectory comprises a series of overlapping segments, and the operations further comprise: iterating act (c), each successive iteration having the desired trajectory being a successive segment of the series of overlapping segments; wherein, for each segment after an initial one of the segments, the posterior mean is further dependent on the determined posterior mean of one or more preceding ones of the segments; and wherein the optimized system input is dependent on the respective posterior means of all the overlapping segments.

Example 12 is an apparatus comprising: one or more hardware processors, with memory coupled thereto; computer-readable media storing instructions which, when executed by the one or more hardware processors, causes the one or more hardware processors to perform operations comprising: (a) obtaining a model of a dynamical system which generates a system output responsive to a system input, wherein the model is configured to receive a description of the system input and produce a corresponding prediction of the system output; for a Gaussian process representation of the system input having a mean and a covariance matrix: (b) selecting a kernel function, having one or more selectable parameters, to impose a prior probability distribution on the covariance matrix of the system input; (c) obtaining a desired trajectory of the system output; wherein a posterior mean of the system input, which is predicted to lead to the desired trajectory, is dependent on the kernel function, the model, and the desired trajectory of the system output; (d) determining respective value(s) of the one or more selectable parameters which optimize a predetermined metric based at least partly on a tracking error between the desired trajectory and the system output; and (c) determining the posterior mean of the Gaussian process corresponding to the determined parameter values and the desired trajectory; and (f) outputting a description of optimized system input for the desired trajectory based on the determined posterior mean.

Example 13 includes the subject matter of Example 12, and further specifies that the operations further comprise: (g) applying the optimized system input to the dynamical system.

Example 14 includes the subject matter of any of Examples 12-13, and further specifies that the desired trajectory comprises a spatial coordinate as a function of time.

Example 15 includes the subject matter of any of Examples 12-14, and further specifies that the system input comprises a time-varying electrical signal.

Example 16 includes the subject matter of Example 15, and further specifies that the time-varying electrical signal drives a stepper motor.

Example 17 includes the subject matter of any of Examples 12-16, and further includes a machine tool, wherein the dynamical system is the machine tool.

Example 18 includes the subject matter of any of Examples 12-17, and further includes a vehicle, wherein the dynamical system is the vehicle.

Example 19 includes the subject matter of any of Examples 12-18, and further specifies that a composite trajectory comprises a series of overlapping segments, and the operations further comprise: iterating act (c), each successive iteration having the desired trajectory being a successive segment of the series of overlapping segments; wherein, for each segment after an initial one of the segments, the posterior mean is further dependent on the determined posterior mean of one or more preceding ones of the segments; and wherein the optimized system input is dependent on the respective posterior means of all the overlapping segments.

Example 20 is a machine tool, including: a feedforward controller, comprising: the apparatus of any one of Examples 12-16 or 19; and a motor drive; wherein the operations further comprise: (d2) determining whether the optimized metric satisfies a predetermined criterion; and (g) applying the optimized system input to the dynamical system; wherein operations (f) and (g) are performed responsive to determining that the optimized metric satisfies the predetermined criterion; and the dynamical system, comprising: a tool head; and a motor coupled to move the tool head; wherein the optimized system input is applied by the motor drive to the motor, so as to move the tool head along the desired trajectory to within a predetermined tolerance, the tool head thereby performing a desired machining operation on a proximate workpiece.

### A Generalized Computer Environment

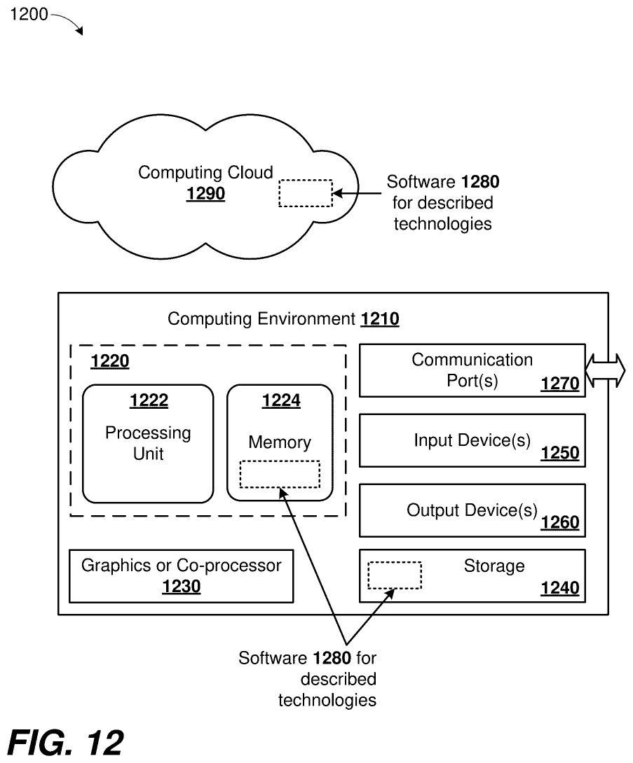

FIG. 12 illustrates a generalized example of a suitable computing system 1200 in which described examples, techniques, and technologies, including construction, deployment, operation, and maintenance of software for feedforward control can be implemented according to disclosed technologies. The computing system 1200 is not intended to suggest any limitation as to scope of use or functionality of the present disclosure, as the innovations can be implemented in diverse general-purpose or special-purpose computing systems.

With reference to FIG. 12, computing environment 1210 includes one or more processing units 1222 and memory 1224. In FIG. 12, this basic configuration 1220 is included within a dashed line. Processing unit 1222 executes computer-executable instructions, such as for implementing any of the methods or objects described herein for implementing feedforward control or associated tasks; or various other architectures, software components, handlers, managers, modules, or services described herein. Processing unit 1222 can be a general-purpose central processing unit (CPU), a processor in an application-specific integrated circuit (ASIC), or any other type of processor. In a multi-processing system, multiple processing units execute computer-executable instructions to increase processing power. Computing environment 1210 can also include a graphics processing unit or co-processing unit 1230. Tangible memory 1224 can be volatile memory (e.g., registers, cache, or RAM), non-volatile memory (e.g., ROM, EEPROM, or flash memory), or some combination thereof, accessible by processing units 1222, 1230. The memory 1224 stores software 1280 implementing one or more innovations described herein, in the form of computer-executable instructions suitable for execution by the processing unit(s) 1222, 1230. The memory 1224 can also store system measurements, model representations, values of kernel parameters, input or output data, tracking error, metric values; other configuration data, data structures including data tables, working tables, change logs, output structures, data values, indices, or flags, as well as other operational data.

A computing system 1210 can have additional features, such as one or more of storage 1240, input components 1250, output components 1260, or communication ports 1270. An interconnection mechanism (not shown) such as a bus, controller, or network interconnects the hardware components of the computing environment 1210. Typically, operating system software (not shown) provides an operating environment for other software executing in the computing environment 1210, and coordinates activities of the hardware and software components of the computing environment 1210.

The tangible storage 1240 can be removable or non-removable, and includes magnetic disks, magnetic tapes or cassettes, CD-ROMs, DVDs, or any other medium which can be used to store information in a non-transitory way and which can be accessed within the computing environment 1210. The storage 1240 stores instructions of the software 1280 (including instructions and/or data) implementing one or more innovations described herein.

The input component(s) 1250 can be a mechanical, touch-sensing, or proximity-sensing input component such as a keyboard, mouse, pen, touchscreen, trackball, a voice input component, a scanning component, or another component that provides input to the computing environment 1210. The output component(s) 1260 can be a display, printer, speaker, optical disk writer, or another component that provides output from the computing environment 1210.

The communication port(s) 1270 enable communication over a communication medium to another computing device. The communication medium conveys information such as computer-executable instructions or other data in a modulated data signal. A modulated data signal is a signal that has one or more of its characteristics set or changed in such a manner as to encode information in the signal. By way of example, and not limitation, communication media can use an electrical, optical, RF, acoustic, or other carrier.

In some examples, computer system 1200 can also include a computing cloud 1290 in which instructions implementing all or a portion of the disclosed technologies are executed. Any combination of memory 1224, storage 1240, and computing cloud 1290 can be used to store software instructions or data of the disclosed technologies.

The present innovations can be described in the general context of computer-executable instructions, such as those included in program modules, being executed in a computing system on a target real or virtual processor. Generally, program modules or software components include routines, programs, libraries, software objects, classes, data structures, etc. which perform tasks or implement particular abstract data types. The functionality of the program modules can be combined or split between program modules as desired in various embodiments. Computer-executable instructions for program modules can be executed within a local or distributed computing system.

The terms “system,” “environment,” and “device” are used interchangeably herein. Unless the context clearly indicates otherwise, none of these terms implies any limitation on a type of computing system, computing environment, or computing device. In general, a computing system, computing environment, or computing device can be local or distributed, and can include any combination of special-purpose hardware and/or general-purpose hardware and/or virtualized hardware, together with software implementing the functionality described herein. Occasionally, the term “computer” is used to refer to a computing system. Virtual processors, virtual hardware, and virtualized devices are ultimately embodied in a hardware processor or another form of physical computer hardware, and thus include both software associated with virtualization and underlying hardware.

### Example Cloud Computing Environment

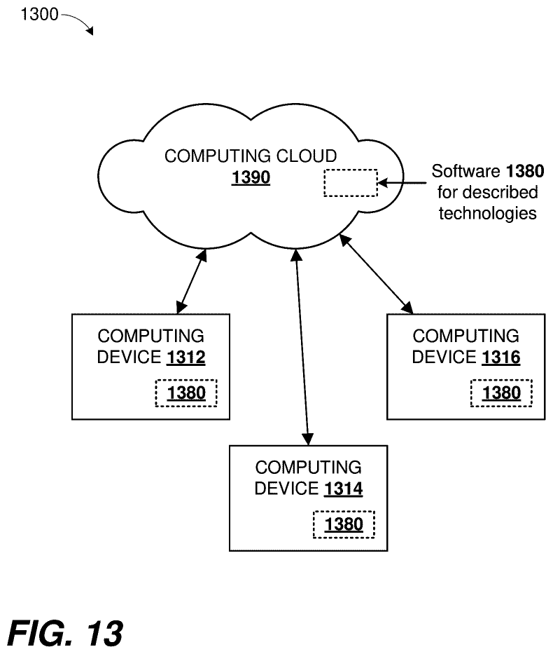

FIG. 13 depicts an example cloud computing environment 1300 in which the described technologies can be implemented. The cloud computing environment 1300 comprises a computing cloud 1390 containing resources and providing services. The computing cloud 1390 can comprise various types of cloud computing resources, such as computer servers, data storage repositories, networking resources, and so forth. The computing cloud 1390 can be centrally located (e.g., provided by a data center of a business or organization) or distributed (e.g., provided by various computing resources located at different locations, such as different data centers and/or located in different cities or countries).

The computing cloud 1390 can be operatively connected to various types of computing devices (e.g., client computing devices), such as computing devices 1312, 1314, and 1316, and can provide a range of computing services thereto. One or more of computing devices 1312, 1314, and 1316 can be computers (e.g., servers, virtual machines, embedded systems, desktop, or laptop computers), mobile devices (e.g., tablet computers, smartphones, or wearable appliances), or other types of computing devices. Communication links between computing cloud 1390 and computing devices 1312, 1314, and 1316 can be over wired, wireless, or optical links, or any combination thereof, and can be short-lived or long-lasting. Communication links can be continuous or sporadic. These communication links can be stationary or can move over time, being implemented over varying paths and having varying attachment points at each end. Computing devices 1312, 1314, and 1316 can also be connected to each other.

Computing devices 1312, 1314, and 1316 can utilize the computing cloud 1390 to obtain computing services and perform computing operations (e.g., data processing, data storage, and the like). Particularly, software 1380 for performing the described innovative technologies can be resident or executed in the computing cloud 1390, in computing devices 1312, 1314, and 1316, or in a distributed combination of cloud and computing devices.

### GENERAL CONSIDERATIONS

As used in this disclosure, the singular forms “a,” “an,” and “the” include the plural forms unless the surrounding language clearly dictates otherwise. Additionally, the terms “includes” and “incorporates” mean “comprises.” Further, the terms “coupled” or “attached” encompass mechanical, electrical, magnetic, optical, as well as other practical ways of coupling items together, and do not exclude the presence of intermediate elements between the coupled items. Furthermore, as used herein, the terms “or” and “and/or” mean any one item or combination of items in the phrase.

Although the operations of some of the disclosed methods are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed things and methods can be used in conjunction with other things and methods. Additionally, the description sometimes uses terms like “acquire,” “analyze,” “apply,” “configure,” “decide,” “determine,” “evaluate,” “generate,” “iterate,” “measure,” “obtain,” “optimize,” “output,” “predict,” “produce,” “receive,” “select,” “store,” “transmit,” or “use” to indicate computer operations in a computer system. These terms denote actual operations that are performed by a computer or controlled by a computer. The actual operations that correspond to these terms will vary depending on the particular implementation and are readily discernible by one of ordinary skill in the art.

Theories of operation, scientific principles, or other theoretical descriptions presented herein in reference to the apparatus or methods of this disclosure have been provided for the purposes of better understanding and are not intended to be limiting in scope. The apparatus and methods in the appended claims are not limited to those apparatus and methods that function in the manner described by such theories of operation.

Any of the disclosed methods can be implemented as computer-executable instructions or a computer program product stored on one or more computer-readable storage media, such as tangible, non-transitory computer-readable storage media, and executed on a computing device (e.g., any available computing device, including tablets, smartphones, or other mobile devices that include computing hardware). Tangible computer-readable storage media are any available tangible media that can be accessed within a computing environment (e.g., one or more optical media discs such as DVD or CD, volatile memory components (such as DRAM or SRAM), or nonvolatile memory components (such as flash memory or hard drives)). By way of example, and with reference to FIG. 12, computer-readable storage media include memory 1224, and storage 1240. The terms computer-readable media and computer-readable storage media do not include signals and carrier waves. In addition, the terms computer-readable media and computer-readable storage media do not include communication ports (e.g., 1270) or communication media.

Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network, a cloud computing network, or other such network) using one or more network computers.

For clarity, only certain selected aspects of the software-based implementations are described. Other details that are well known in the art are omitted. For example, it should be understood that the disclosed technologies are not limited to any specific computer language or program. For instance, the disclosed technologies can be implemented by software written in ABAP, Adobe Flash, Angular, C, C++, C#, Curl, Dart, Fortran, Go, Java, JavaScript, Julia, Lisp, Matlab, Octave, Perl, Python, R, Ruby, SAS, SPSS, WebAssembly, any derivatives thereof, or any other suitable programming language, or, in some examples, markup languages such as HTML or XML, or in any combination of suitable languages, libraries, and packages. Likewise, the disclosed technologies are not limited to any particular computer or type of hardware. Certain details of suitable computers and hardware are well known and need not be set forth in detail in this disclosure.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, infrared, and optical communications), electronic communications, or other such communication means.

The disclosed methods, apparatus, and systems should not be construed as limiting in any way. Instead, the present disclosure is directed toward all novel and nonobvious features and aspects of the various disclosed embodiments, alone and in various combinations and sub-combinations with one another. The disclosed methods, apparatus, and systems are not limited to any specific aspect or feature or combination thereof, nor do embodiments of the disclosed technologies require that any one or more specific advantages be present or problems be solved. The technologies from any example can be combined with the technologies described in any one or more of the other examples.

In view of the many possible embodiments to which the principles of the disclosed technologies may be applied, it should be recognized that the illustrated embodiments are only preferred examples and should not be taken as limiting the scope of the claims. We therefore claim all that comes within the scope and spirit of these claims.

In view of the many possible embodiments to which the principles of the disclosed invention may be applied, it should be recognized that the illustrated embodiments are only preferred examples of the invention and should not be taken as limiting the scope of the claims. We therefore claim all that comes within the scope and spirit of these claims.

We claim:

1. A method, comprising:
(a) obtaining a model of a dynamical system which generates a system output responsive to a system input, wherein the model is configured to receive a description of the system input and produce a corresponding prediction of the system output;
for a Gaussian process representation of the system input having a mean and a covariance matrix:
(b) selecting a kernel function, having one or more selectable parameters, to impose a prior probability distribution on the covariance matrix of the system input;
(c) obtaining a desired trajectory of the system output;
wherein a posterior mean of the system input, which is predicted to lead to the desired trajectory, is dependent on the kernel function, the model, and the desired trajectory of the system output;
(d) determining respective value(s) of the one or more selectable parameters which optimize a predetermined metric based at least partly on a tracking error between the desired trajectory and the system output; and
(e) determining the posterior mean of the Gaussian process corresponding to the determined parameter values and the desired trajectory; and
(f) outputting a description of optimized system input for the desired trajectory based on the determined posterior mean.

2. The method of claim 1, further comprising:
performing measurements on the dynamical system;
wherein the obtaining is based on results of the measurements.

3. The method of claim 1, further comprising:
applying the optimized system input to the dynamical system.

4. The method of claim 1, wherein the desired trajectory comprises a spatial coordinate as a function of time.

5. The method of claim 1, further comprising:
(d2) determining whether the optimized metric satisfies a predetermined criterion;
wherein act (f) is performed responsive to determining, in at least a given instance, that the optimized metric satisfies the predetermined criterion.

6. The method of claim 5, further comprising:
performing first and second iterations of acts (d) and (d2) with the selected kernel function being first and second kernel functions respectively;
performing the second iteration responsive to determining on the first iteration that the optimized metric for the first kernel function does not satisfy the predetermined metric; and
determining on the second iteration that the optimized metric for the second kernel function satisfies the predetermined metric.

7. The method of claim 1, wherein a composite trajectory comprises a series of overlapping segments, and the method further comprises:
iterating act (c), each successive iteration having the desired trajectory being a successive segment of the series of overlapping segments;
wherein, for each segment after an initial one of the segments, the posterior mean is further dependent on the determined posterior mean of one or more preceding ones of the segments; and
wherein the optimized system input is dependent on the respective posterior means of all the overlapping segments.

8. One or more computer-readable media storing instructions which, when executed by one or more hardware processors, cause the one or more hardware processors to perform operations comprising:
(a) obtaining a model of a dynamical system which generates a system output responsive to a system input, wherein the model is configured to receive a description of the system input and produce a corresponding prediction of the system output;
for a Gaussian process representation of the system input having a mean and a covariance matrix:
(b) selecting a kernel function, having one or more selectable parameters, to impose a prior probability distribution on the covariance matrix of the system input;
(c) obtaining a desired trajectory of the system output;
wherein a posterior mean of the system input, which is predicted to lead to the desired trajectory, is dependent on the kernel function, the model, and the desired trajectory of the system output;
(d) determining respective value(s) of the one or more selectable parameters which optimize a predetermined metric based at least partly on a tracking error between the desired trajectory and the system output; and
(e) determining the posterior mean of the Gaussian process corresponding to the determined parameter values and the desired trajectory; and
(f) outputting a description of optimized system input for the desired trajectory based on the determined posterior mean.

9. The one or more computer-readable media of claim 8, wherein the predetermined metric is further based at least partly on smoothness of the mean of the system input.

10. The one or more computer-readable media of claim 8, wherein the operations further comprise:
performing multiple iterations of acts (b) and (d) with respective selected kernel functions; and
performing the operations (e) and (f) for one of the kernel functions having a best value of the optimized metric.

11. The one or more computer-readable media of claim 8, wherein a composite trajectory comprises a series of overlapping segments, and the operations further comprise:
iterating act (c), each successive iteration having the desired trajectory being a successive segment of the series of overlapping segments;
wherein, for each segment after an initial one of the segments, the posterior mean is further dependent on the determined posterior mean of one or more preceding ones of the segments; and
wherein the optimized system input is dependent on the respective posterior means of all the overlapping segments.

12. An apparatus comprising:
one or more hardware processors, with memory coupled thereto;
computer-readable media storing instructions which, when executed by the one or more hardware processors, causes the one or more hardware processors to perform operations comprising:
(a) obtaining a model of a dynamical system which generates a system output responsive to a system input, wherein the model is configured to receive a description of the system input and produce a corresponding prediction of the system output;
for a Gaussian process representation of the system input having a mean and a covariance matrix:
(b) selecting a kernel function, having one or more selectable parameters, to impose a prior probability distribution on the covariance matrix of the system input;
(c) obtaining a desired trajectory of the system output;
wherein a posterior mean of the system input, which is predicted to lead to the desired trajectory, is dependent on the kernel function, the model, and the desired trajectory of the system output;
(d) determining respective value(s) of the one or more selectable parameters which optimize a predetermined metric based at least partly on a tracking error between the desired trajectory and the system output; and
(e) determining the posterior mean of the Gaussian process corresponding to the determined parameter values and the desired trajectory; and
(f) outputting a description of optimized system input for the desired trajectory based on the determined posterior mean.

13. The apparatus of claim 12, wherein the operations further comprise:
(g) applying the optimized system input to the dynamical system.

14. The apparatus of claim 12, wherein the desired trajectory comprises a spatial coordinate as a function of time.

15. The apparatus of claim 12, wherein the system input comprises a time-varying electrical signal.

16. The apparatus of claim 15, wherein the time-varying electrical signal drives a stepper motor.

17. The apparatus of claim 12, further comprising a machine tool, wherein the dynamical system is the machine tool.

18. The apparatus of claim 12, further comprising a vehicle, wherein the dynamical system is the vehicle.

19. The apparatus of claim 12, wherein a composite trajectory comprises a series of overlapping segments, and the operations further comprise:
iterating act (c), each successive iteration having the desired trajectory being a successive segment of the series of overlapping segments;
wherein, for each segment after an initial one of the segments, the posterior mean is further dependent on the determined posterior mean of one or more preceding ones of the segments; and
wherein the optimized system input is dependent on the respective posterior means of all the overlapping segments.

20. A machine tool comprising:
a feedforward controller, comprising:
the apparatus of claim 12; and
a motor drive;
wherein the operations further comprise:
(d2) determining whether the optimized metric satisfies a predetermined criterion; and
(g) applying the optimized system input to the dynamical system;
wherein operations (f) and (g) are performed responsive to determining that the optimized metric satisfies the predetermined criterion; and
the dynamical system, comprising:
a tool head; and
a motor coupled to move the tool head;
wherein the optimized system input is applied by the motor drive to the motor, so as to move the tool head along the desired trajectory to within a predetermined tolerance, the tool head thereby performing a desired machining operation on a proximate workpiece.
